(19) United States
(12) Patent Application Publication
(10) Pub. No.: US 2011/0291294 A1
(43) Pub. Date: Dec. 1, 2011

(54) Multi-Chip Package

(75) Inventors: Sang-Uk Kim, Cheonan-si (KR); Jin-woo Park, Seoul (KR); Dae-Young Choi, Jeollanam-do (KR); Mi-Yeon Kim, Chungcheongnam-do (KR); Sun-Hye Lee, Cheongju-si (KR)

(73) Assignee: SAMSUNG ELECTRONICS CO., LTD., Suwon-si (KR)

(21) Appl. No.: 13/049,377

(22) Filed: Mar. 16, 2011

(30) Foreign Application Priority Data
May 27, 2010 (KR) 10-2010-0049422

(51) Int. Cl. H01L 23/52

(52) U.S. Cl. 257/777; 257/E23.141

(57) ABSTRACT

A multi-chip package may include a first semiconductor package, a second semiconductor package and an interposer chip. The second semiconductor package may be arranged over the first semiconductor package. The interposer chip may be interposed between the first semiconductor package and the second semiconductor package. The interposer chip may have a receiving groove configured to receive the first semiconductor package. Thus, electrical connection reliability between the first semiconductor package and the second semiconductor package may be improved under a condition that the connecting terminals may have small sizes.

### CROSS-RELATED APPLICATION

This application claims priority under 35 USC §119 to Korean Patent Application No. 2010-0049422, filed on May 27, 2010 in the Korean Intellectual Property Office (KIPO), the contents of which are herein incorporated by reference in their entirety.

### BACKGROUND

1. Field

Example embodiments relate to a multi-chip package and a method of manufacturing the same. More particularly, example embodiments relate to a multi-chip package including sequentially stacked semiconductor chips, and a method of manufacturing the multi-chip package.

2. Description of the Related Art

Generally, a plurality of semiconductor fabrication processes may be performed on a semiconductor substrate to form a plurality of semiconductor chips. In order to mount the semiconductor chips on a printed circuit board (PCB), a packaging process may be performed on the semiconductor chips to form semiconductor packages. In order to increase a storage capacity of the semiconductor package, a multi-chip package including sequentially stacked semiconductor chips may be widely studied.

A conventional multi-chip package includes a first semiconductor package, a second semiconductor package, and external terminals. The second semiconductor package is arranged over the first semiconductor package. The first semiconductor package includes first connecting terminals. The first connecting terminals are mounted on a lower surface of a first package substrate in the first semiconductor package. Second connecting terminals are interposed between the first semiconductor package and the second semiconductor package to electrically connect the first package substrate of the first semiconductor package with a second package substrate of the second semiconductor package. The external terminals are mounted on a lower surface of the second package substrate.

Because the second connecting terminals are arranged on edge portions of the first package substrate and the second package substrate, the second connecting terminals have a size corresponding to an interval between the first package substrate and the second package substrate. Here, when the second connecting terminals have a large size to improve an electrical connection between the first package substrate and the second package substrate, an electrical short may be generated between the second connecting terminals. In contrast, when the second connecting terminals have a small size to prevent the electrical short between the second connecting terminals, a gap may be formed between the second connecting terminals and the first package substrate, so that the second connecting terminals may not be connected to the first package substrate.

Further, a first semiconductor chip of the first semiconductor package is located at an upper central surface of the first package substrate, so that the second connecting terminals are mounted on the edge portion of the first package substrate. Thus, there exists an application of kinds of a second semiconductor chip to the second semiconductor package. That is, the second connecting terminals of the second semiconductor chip applicable to the second semiconductor package are arranged on the edge portion of the second package substrate. Therefore, a semiconductor chip having second connecting terminals, which are arranged on a whole lower surface of a second package substrate, are not used in the second semiconductor package.

### SUMMARY

Example embodiments provide a multi-chip package capable of preventing an electrical short between connecting terminals regardless of sizes of the connecting terminals, improving electrical connection reliability between the connecting terminals and a package substrate, and adapting to include various kinds of semiconductor chips.

Example embodiments also provide a method of manufacturing the above-mentioned multi-chip package.

In one example embodiment, a multi-chip package includes a first semiconductor package, a second semiconductor package, and an interposer chip. In this example embodiment, the first semiconductor package includes a first semiconductor chip on a first package substrate, the second semiconductor package includes a second semiconductor chip on a second package substrate, and the interposer chip is between the first semiconductor package and the second semiconductor package. In this example embodiment the interposer chip includes a receiving groove in which the first semiconductor chip is at least partially enclosed and the interposer chip electrically connects the second semiconductor package to the first package substrate.

According to some example embodiments, there is provided a multi-chip package. The multi-chip package may include a first semiconductor package, a second semiconductor package and an interposer chip. The second semiconductor package may be arranged over the first semiconductor package. The interposer chip may be interposed between the first semiconductor package and the second semiconductor package. The interposer chip may have a receiving groove configured to receive the first semiconductor package.

In some example embodiments, the interposer chip may include an interposer substrate having the receiving groove, and interposer terminals mounted on an edge portion of the interposer substrate to electrically connect the first semiconductor package with the second semiconductor package. The receiving groove may be formed at a central portion of a lower surface of the interposer substrate. The interposer substrate may have an upper surface configured to make contact with a lower surface of the second semiconductor package.

In some example embodiments, the first semiconductor package may include a first package substrate, a first semiconductor chip and first connecting terminals. The first semiconductor chip may be arranged over the first package substrate. The first connecting terminals may be interposed between the first semiconductor chip and the first package substrate to electrically connect the first semiconductor chip with the first package substrate. The first package substrate may have a width greater than that of the interposer chip. Passive elements may be arranged on an edge portion of an upper surface of the first package substrate exposed by the interposer chip.

In some example embodiments, the second semiconductor package may include a second package substrate, a second semiconductor chip and second connecting terminals. The second package substrate may be arranged over the first semiconductor package. The second semiconductor chip may be arranged on the second package substrate. The second semiconductor chip may be electrically connected to the second package substrate. The second connecting terminals may be interposed between the interposer chip and the second package substrate to electrically connect the interposer chip with the second package substrate.

In some example embodiments, the multi-chip package may further include external terminals mounted on a lower surface of the first semiconductor package.

According to some example embodiments, there is provided a method of manufacturing a multi-chip package. In the method of manufacturing the multi-chip package, a first semiconductor package may be received in a receiving groove of a lower surface of an interposer chip. A second semiconductor package may be mounted on an upper surface of the interposer chip.

In some example embodiments, the method may further include mounting external terminals on a lower surface of the first semiconductor package.

According to some example embodiments, the first connecting terminals and the second connecting terminals may be electrically connected with each other via the interposer chip having the receiving groove configured to receive the first semiconductor package. Thus, electrical connection reliability between the first semiconductor package and the second semiconductor package may be improved under a condition that the connecting terminals may have small sizes. Further, because the second connecting terminals may make contact with the upper surface of the interposer chip, not the first semiconductor chip, the second connecting terminals may be arranged the whole lower surface of the second package substrate. Therefore, kinds of the second semiconductor chip applicable to the second semiconductor package may not be restricted within a specific structure.

### BRIEF DESCRIPTION OF THE DRAWINGS

Example embodiments will be more clearly understood from the following detailed description taken in conjunction with the accompanying drawings. FIGS. 1 to 8 represent non-limiting, example embodiments as described herein.

FIG. 1 is a cross-sectional view illustrating a multi-chip package in accordance with some example embodiments;

FIG. 2 is a cross-sectional view illustrating an interposer chip of the multi-chip package in FIG. 1;

FIG. 3 is a bottom view illustrating a second package substrate of the multi-chip package in FIG. 1; and

FIGS. 4 to 8 are cross-sectional views illustrating a method of manufacturing the multi-chip package in FIG. 1.

### DETAILED DESCRIPTION OF THE EXAMPLE EMBODIMENTS

Various example embodiments will be described more fully hereinafter with reference to the accompanying drawings, in which some example embodiments are shown. The present invention may, however, be embodied in many different forms and should not be construed as limited to the example embodiments set forth herein. Rather, these example embodiments are provided so that this disclosure will be thorough and complete, and will fully convey the scope of the present invention to those skilled in the art. In the drawings, the sizes and relative sizes of layers and regions may be exaggerated for clarity.

It will be understood that when an element or layer is referred to as being “on,” “connected to” or “coupled to” another element or layer, it can be directly on, connected or coupled to the other element or layer or intervening elements or layers may be present. In contrast, when an element is referred to as being “directly on,” “directly connected to” or “directly coupled to” another element or layer, there are no intervening elements or layers present. Like numerals refer to like elements throughout. As used herein, the term “and/or” includes any and all combinations of one or more of the associated listed items.

It will be understood that, although the terms first, second, third etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of the present invention.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

The terminology used herein is for the purpose of describing particular example embodiments only and is not intended to be limiting of the present invention. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Example embodiments are described herein with reference to cross-sectional illustrations that are schematic illustrations of idealized example embodiments (and intermediate structures). As such, variations from the shapes of the illustrations as a result, for example, of manufacturing techniques and/or tolerances, are to be expected. Thus, example embodiments should not be construed as limited to the particular shapes of regions illustrated herein but are to include deviations in shapes that result, for example, from manufacturing. For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of the present invention.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Hereinafter, example embodiments will be explained in detail with reference to the accompanying drawings.

Multi-Chip Package

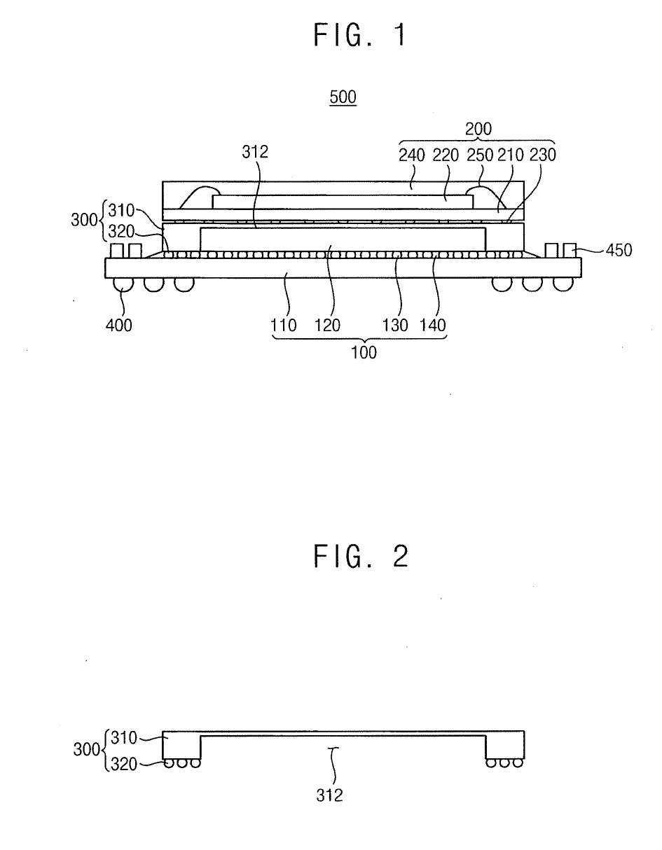

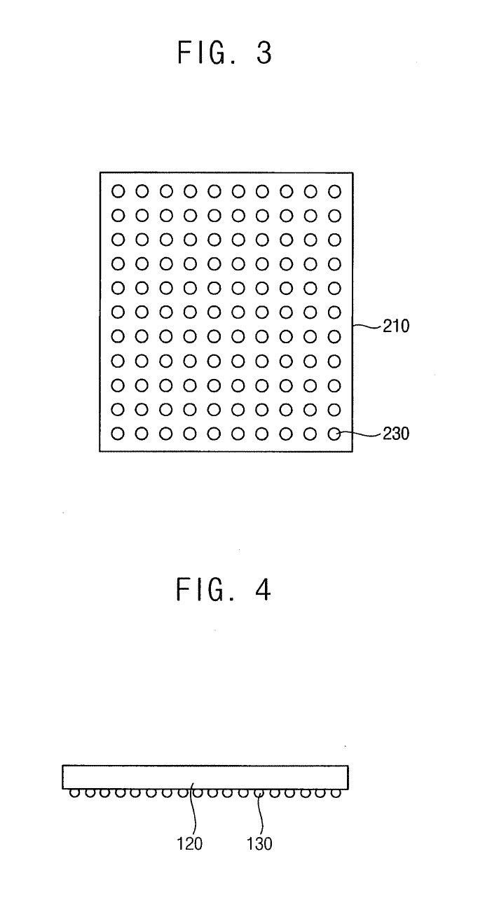

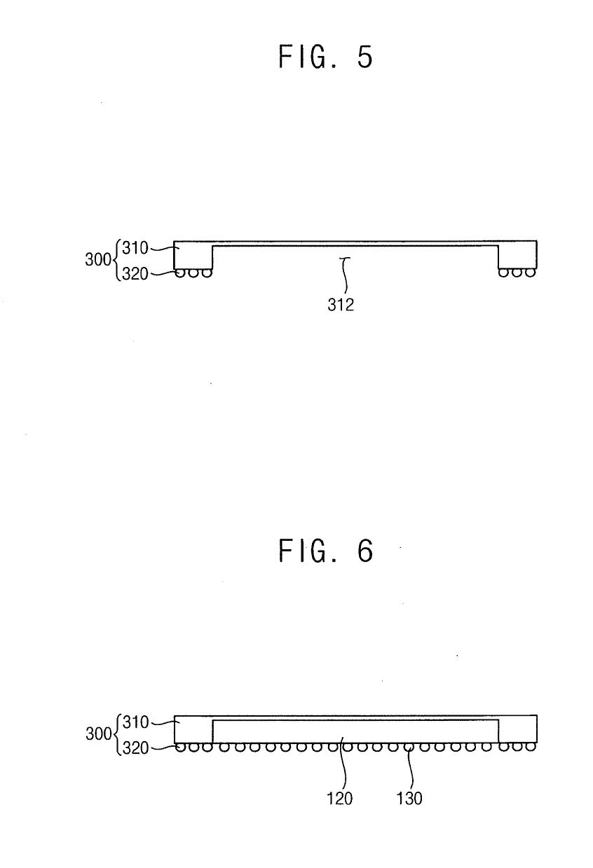

FIG. 1 is a cross-sectional view illustrating a multi-chip package in accordance with some example embodiments, FIG. 2 is a cross-sectional view illustrating an interposer chip of the multi-chip package in FIG. 1, and FIG. 3 is a bottom view illustrating a second package substrate of the multi-chip package in FIG. 1.

Referring to FIGS. 1 to 3, a multi-chip package 500 of this example embodiment may include a first semiconductor package 100, a second semiconductor package 200, interposer chip 300, and external terminals 400.

The first semiconductor package 100 may include a first package substrate 110, a first semiconductor chip 120, first connecting terminals 130, and an underfilling layer 140.

The first package substrate 110 may include an insulating substrate (not shown) and a circuit pattern (not shown). The circuit pattern may be built in the insulating substrate. The circuit pattern may be exposed through an upper surface and a lower surface of the insulating substrate. The exposed portions of the circuit pattern may correspond to lands on which connecting terminals may be mounted.

The first semiconductor chip 120 may be arranged over the first package substrate 110. Thus, a gap may be formed between the first semiconductor chip 120 and the first package substrate 110. In some example embodiments, the first semiconductor chip 120 may include a flip chip. Therefore, the first semiconductor chip 120 may have bonding pads oriented toward the first package substrate 110. That is, the bonding pads may be arranged on a lower surface of the first semiconductor chip 120. Alternatively, the first semiconductor chip 120 may include a lead frame, bonding wires, etc.

The first connecting terminals 130 may be mounted on the bonding pads of the first semiconductor chip 120. The first connecting terminals 130 may be electrically connected to the circuit pattern of the first package substrate 110. Thus, the first semiconductor chip 120 may be electrically connected to the first package substrate 110 via the first connecting terminals 130. In some example embodiments, the first connecting terminals 130 may include a solder ball, a solder bump, etc.

The underfilling layer 140 may be formed between the first package substrate 110 and the first semiconductor chip 120 to prevent the first connecting terminals 130 from being exposed. The underfilling layer 140 may protect the first connecting terminals 130 from external environments. In some example embodiments, the underfilling layer 140 may include an epoxy molding compound (EMC).

The second semiconductor package 200 may include a second package substrate 210, a second semiconductor chip 220, second connecting terminals 230, a molding member 240, and conductive connecting members 250.

In some example embodiments, the second package substrate 210 may have a width less than that of the first package substrate 110. Thus, an upper edge surface of the first package substrate 110 may be exposed by the second package substrate 210. Passive elements 450 such as a capacitor or an inductor may be mounted on the exposed upper edge surface of the first package substrate 110.

The second package substrate 210 may include an insulating substrate (not shown) and a circuit pattern (not shown). The circuit pattern may be built in the insulating substrate. The circuit pattern may be exposed through an upper surface and a lower surface of the insulating substrate. The exposed portions of the circuit pattern may correspond to lands on which the connecting terminals may be mounted. In some example embodiments, the circuit pattern may be exposed through the whole lower surface of the second package substrate 210. In contrast, the circuit pattern may be exposed through an upper edge surface of the second package substrate 210.

The second semiconductor chip 220 may be arranged on an upper central surface of the second package substrate 210. Thus, a gap may not be formed between the second semiconductor chip 220 and the second package substrate 210. In some example embodiments, the second semiconductor chip 220 may have bonding pads oriented against the second package substrate 210. That is, the bonding pads may be arranged on the upper edge surface of the package substrate 210. Alternatively, the second semiconductor chip 220 may include a flip chip.

The second connecting terminals 230 may be mounted on the lower surface of the second package substrate 210. That is, the second connecting terminals 230 may be mounted on the circuit pattern exposed through the lower surface of the second package substrate 210. In some example embodiments, the second connecting terminals 230 may include a solder ball, a solder bump, etc.

The conductive connecting members 250 may be electrically connected between the bonding pads of the second semiconductor chip 220 and the circuit pattern exposed through the upper surface of the second package substrate 210. Thus, the second semiconductor chip 220 may be electrically connected to the second package substrate 210 via the conductive connecting members 250. In some example embodiments, the conductive connecting members 250 may include a metal wire such as a gold wire, an aluminum wire, etc.

The molding member 240 may be formed on the second package substrate 210 and the second semiconductor chip 220 to cover the conductive connecting members 250. The molding member 240 may protect the second semiconductor chip 220 and the second connecting terminals 230 from external environments. In some example embodiments, the molding member 240 may include an epoxy molding compound (EMC).

The interposer chip 300 may be interposed between the first semiconductor package 100 and the second semiconductor package 200. The interposer chip 300 may include an interposer substrate 310 and interposer terminals 320.

In some example embodiments, the interposer substrate 310 may physically make contact with the first semiconductor chip 120. The interposer substrate 310 may not be electrically connected with the first semiconductor chip 120. The interposer substrate 310 may have a receiving groove 312 configured to receive the first semiconductor chip 120. The receiving groove 312 may be formed at a lower central surface of the interposer substrate 310. The receiving groove 312 may have a size corresponding to a size of the first semiconductor chip 120. Thus, the receiving groove 312 may have a side surface and an upper surface configured to make contact with a side surface and an upper surface of the first semiconductor chip 120, respectively. Alternatively, a minute gap may be formed between the side surface of the receiving groove 312 and the side surface of the first semiconductor chip 120. In addition, a minute gap may be formed between the upper surface of the first semiconductor chip 120 and the upper surface of the receiving groove 312.

In some example embodiments, the interposer substrate 310 may have a width substantially the same as that of the second package substrate 210. Thus, the upper edge surface of the first package substrate 110 may be exposed by the interposer substrate 310.

In some example embodiments, the interposer substrate 310 may have a lower surface substantially coplanar with that of the first semiconductor chip 120. Thus, the lower surface of the first semiconductor chip 120 may not be protruded from the lower surface of the interposer substrate 310. Although not depicted in drawings, a circuit pattern may be built in the interposer substrate 310. The circuit pattern may be exposed through an upper surface and a lower surface of the interposer substrate 310. The circuit pattern may be arranged on the whole upper surface of the interposer substrate 310.

The second connecting terminals 230 of the second semiconductor package 200 may be mounted on the exposed circuit pattern through the upper surface of the interposer substrate 310. In some example embodiments, because the circuit pattern may be arranged on the whole upper surface of the interposer substrate 310, positions of the second connecting terminals 230 may not be restricted within a specific position. That is, the second semiconductor package 200, which may have a structure where the second connecting terminals 230 may be arranged on the whole lower surface of the second package substrate 210, a structure where the second connecting terminals 230 may be arranged on the lower central surface of the second package substrate 210, or a structure where the second connecting terminals 230 may be arranged on a lower edge surface of the second package substrate 210, may be stacked on the first semiconductor package 100 using the interposer chip 300. Therefore, various kinds of the second semiconductor packages 200 adapted to be stacked on the first semiconductor package 100 may not be restricted due to the interposer chip 300.

In some example embodiments, a gap between the interposer substrate 310 and the second package substrate 210 may be arbitrarily adjusted. Thus, sizes of the second connecting terminals 230 between the interposer substrate 310 and the second package substrate 210 may not be restricted within a specific range. Therefore, the second connecting terminals 230 may have a relatively small size and yet guarantee an electrical connection between the interposer substrate 310 and the second package substrate 210. As a result, the multi-chip package 500 may have a relatively thin thickness.

The interposer terminals 320 may be mounted on the lower surface of the interposer substrate 310. That is, the interposer terminals 320 may be mounted on the circuit pattern exposed through the lower surface of the interposer substrate 310. Thus, the second semiconductor chip 220 may be electrically connected to the first package substrate 110 via the conductive connecting members 250, the second package substrate 210, the second connecting terminals 230, the interposer substrate 310 and the interposer terminals 320.

In some example embodiments, the interposer terminals 320 may have a structure and a material substantially the same as those of the first connecting terminals 130. That is, the interposer terminals 320 may be formed simultaneously with the first connecting terminals 130. Thus, the interposer terminals 320 may include a solder ball, a solder bump, etc. Alternatively, the interposer terminals 320 may be formed by a process different from a process for forming the first connecting terminals 130. The underfilling layer 140 may be formed between the interposer substrate 310 and the first package substrate 110 to cover the interposer terminals 320.

In some example embodiments, a gap between the interposer substrate 310 and the first package substrate 110 may be arbitrarily adjusted. Thus, sizes of the first connecting terminals 130 between the interposer substrate 310 and the first package substrate 110 may not be restricted within a specific range. Therefore, the first connecting terminals 130 may have a relatively small size and yet guarantee an electrical connection between the interposer substrate 310 and the first package substrate 110. As a result, the multi-chip package 500 may have a relatively thin thickness.

The external terminals 400 may be mounted on the lower surface of the first package substrate 110. Thus, the first semiconductor chip 120 may be electrically connected to the external terminals 400 via the first package substrate 110. The second semiconductor chip 220 may be electrically connected to the external terminals 400 via the conductive connecting members 250, the second package substrate 210, the second connecting terminals 230, the interposer substrate 310, the interposer terminals 320, and the first package substrate 110. In some example embodiments, the external terminals 400 may include a solder ball.

According to some example embodiments, the first connecting terminals and the second connecting terminals may be electrically connected with each other via the interposer chip having the receiving groove configured to receive the first semiconductor package. Thus, electrical connection reliability between the first semiconductor package and the second semiconductor package may be improved under a condition that the connecting terminals may have relatively small sizes. Further, because the second connecting terminals may make contact with the upper surface of the interposer chip, not the first semiconductor chip, the second connecting terminals may be arranged the whole lower surface of the second package substrate. Therefore, various kinds of the second semiconductor chips applicable to the second semiconductor package may not be restricted within a specific structure.

Method of Manufacturing a Multi-Chip Package

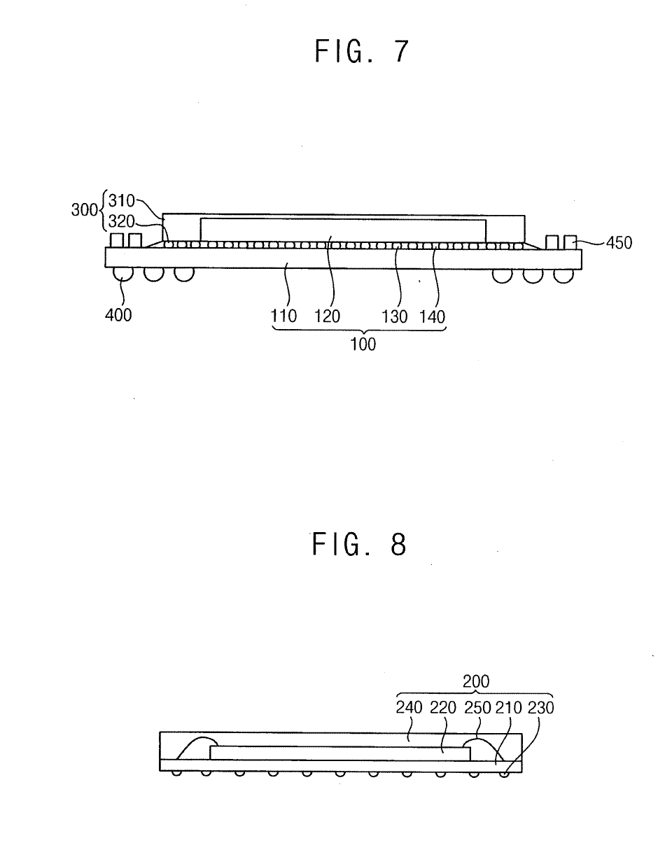

FIGS. 4 to 8 are cross-sectional views illustrating a method of manufacturing the multi-chip package in FIG. 1.

Referring to FIG. 4, the first connecting terminals 130 may be mounted on the bonding pads of the first semiconductor chip 120. In some example embodiments, the first connecting terminals 130 may be formed by a reflow process, a screen printing process, etc.

Referring to FIG. 5, the interposer terminals 320 may be mounted on the lower surface of the interposer substrate 310. In some example embodiments, the interposer terminals 320 may be formed by a reflow process, a screen printing process, etc.

Referring to FIG. 6, the first semiconductor chip 120 may be received in the receiving groove 312 of the interposer chip 300. In some example embodiments, an adhesive (not, shown) may be formed on the inner surface of the receive groove 312 to firmly attach the first semiconductor chip 120 to the inner surface of the receiving groove 312.

In some example embodiments, the first connecting terminals 130 and the interposer terminals 320 may be formed by different processes. Alternatively, after the first semiconductor chip 120 may be received in the receiving groove 312 of the interposer chip 300, the first connecting terminals 130 and the interposer terminals 320 may be formed by substantially the same process.

Referring to FIG. 7, the first semiconductor chip 120 and the interposer chip 300 may be mounted on the upper surface of the first package substrate 110. That is, the first connecting terminals 130 and the interposer terminals 320 may be mounted on the circuit pattern exposed through the upper surface of the first package substrate 110.

The external terminals 400 may be mounted on the lower surface of the first package substrate 110. The passive elements 450 may be mounted on the upper edge surface of the first package substrate 110.

In some example embodiments, before stacking the second semiconductor package 200 on the first semiconductor package 100, the external terminals 400 may be mounted on the lower surface of the first package substrate 110. Alternatively, after stacking the second semiconductor package 200 on the first semiconductor package 100, the external terminals 400 may be mounted on the lower surface of the first package substrate 110.

In some example embodiment, before stacking the second semiconductor package 200 on the first semiconductor package 100, the passive elements 450 may be mounted on the upper edge surface of the first package substrate 110. Alternatively, after stacking the second semiconductor package 200 on the first semiconductor package 100, the passive elements 450 may be mounted on the upper edge surface of the first package substrate 110.

Referring to FIG. 8, the second semiconductor package 200 may be prepared. In some example embodiments, the second semiconductor chip 220 may be arranged on the second package substrate 210. The conductive connecting members 250 may be electrically connected between the bonding pads of the second semiconductor chip 220 and the circuit pattern of the second package substrate 210. The second connecting terminals 230 may be mounted on the lower surface of the second package substrate 210. The molding member 240 may be formed on the second package substrate 210 and the second semiconductor chip 220 to cover the second semiconductor chip 220 and the conductive connecting members 250. In some example embodiments, the second connecting terminals 230 may be formed by a reflow process, a screen printing process, etc.

The second semiconductor package 200 may be stacked on the interposer chip 300 to complete the multi-chip package 500 in FIG. 1. In some example embodiments, the second connecting terminals 230 may be mounted on the circuit pattern exposed through the upper surface of the interposer substrate 310.

According to these example embodiments, the first connecting terminals and the second connecting terminals may be electrically connected with each other via the interposer chip having the receiving groove configured to receive the first semiconductor package. Thus, electrical connection reliability between the first semiconductor package and the second semiconductor package may be improved under a condition that the connecting terminals may have relatively small sizes. Further, because the second connecting terminals may make contact with the upper surface of the interposer chip, rather than the first semiconductor chip, the second connecting terminals may be arranged on the whole lower surface of the second package substrate. Therefore, various kinds of the second semiconductor chip applicable to the second semiconductor package may not be restricted within a specific structure.

The foregoing is illustrative of example embodiments and is not to be construed as limiting thereof. Although a few example embodiments have been described, those skilled in the art will readily appreciate that many modifications are possible in the example embodiments without materially departing from the novel teachings and advantages of the present invention. Accordingly, all such modifications are intended to be included within the scope of the present invention as defined in the claims. In the claims, means-plus-function clauses are intended to cover the structures described herein as performing the recited function and not only structural equivalents but also equivalent structures. Therefore, it is to be understood that the foregoing is illustrative of various example embodiments and is not to be construed as limited to the specific example embodiments disclosed, and that modifications to the disclosed example embodiments, as well as other example embodiments, are intended to be included within the scope of the appended claims.

1. A multi-chip package comprising:
a first semiconductor package;
a second semiconductor package over the first semiconductor package; and
an interposer chip between the first semiconductor package and the second semiconductor package, the interposer chip having a receiving groove configured to receive the first semiconductor package.

2. The multi-chip package of claim 1, wherein the interposer chip comprises:
an interposer substrate having the receiving groove; and
interposer terminals on a lower edge surface of the interposer substrate, the interposer terminals electrically connecting the first semiconductor package to the second semiconductor package.

3. The multi-chip package of claim 2, wherein the receiving groove is at a lower central surface of the interposer substrate.

4. The multi-chip package of claim 2, wherein the interposer substrate has an upper surface contacting a lower surface of the second semiconductor package.

5. The multi-chip package of claim 1, wherein the first semiconductor package comprises:
a first package substrate;
a first semiconductor chip over the first package substrate; and
first connecting terminals between the first semiconductor chip and the first package substrate, the first connecting terminals electrically connecting the first semiconductor chip to the first package substrate.

6. The multi-chip package of claim 5, wherein the first package substrate has a width greater than that of the interposer chip to arrange passive elements on an upper edge surface of the first package substrate.

7. The multi-chip package of claim 1, wherein the second semiconductor package comprises:
a second package substrate over the first semiconductor package;
a second semiconductor chip over the second package substrate, the second semiconductor chip being electrically connected to the second package substrate; and
second connecting terminals between the interposer chip and the second package substrate, the second connecting terminals electrically connecting the interposer chip to the second package substrate.

8. The multi-chip package of claim 1, further comprising:
external terminals on a lower surface of the first semiconductor package.

9-10. (canceled)

11. A multi-chip package comprising:
a first semiconductor package including a first semiconductor chip on a first package substrate;
a second semiconductor package including a second semiconductor chip on a second package substrate; and
an interposer chip between the first semiconductor package and the second semiconductor package, the interposer chip including a receiving groove in which the first semiconductor chip is at least partially enclosed, the interposer chip electrically connecting the second semiconductor package to the first package substrate.

12. The multi-chip package of claim 11, wherein
the first semiconductor package further includes first connecting terminals between the first semiconductor chip and the first package substrate;
the second semiconductor package further includes second connecting terminals between the second package substrate and the interposer chip; and
the interposer chip further includes an interposer substrate and a plurality of interposer terminals, the interposer terminals being between the interposer substrate and the first package substrate.

13. The multi-chip package of claim 12, wherein the second semiconductor package further includes a conductive connecting member electrically connecting the second semiconductor chip to the second package substrate.

14. The multi-chip package of claim 13, wherein the plurality of interposer terminals, the interposer substrate, the second connecting terminals, and the conductive connecting member electrically connect the second semiconductor chip to the first package substrate.

15. The multi-chip package of claim 11, wherein the receiving groove has a side surface and an upper surface contacting a side surface and an upper surface of the first semiconductor chip.

16. The multi-chip package of claim 11, further comprising:
an adhesive on an inner surface of the receiving groove attaching the first semiconductor chip to the interposer chip.

17. The multi-chip package of claim 11, wherein a width of the interposer chip and a width of the second package substrate are substantially equal and a width of the first package substrate is larger than widths of the interposer chip and the second package substrate.

18. The multi-chip package of claim 11, further comprising:
passive elements on the first package substrate, the passive elements being arranged between an outside edge of the first package substrate and an outside edge of the interposer chip.

19. The multi-chip package of claim 11, wherein the second semiconductor package includes a plurality of connecting terminals between the interposer chip and the second package substrate, at least some of the connecting terminals being arranged directly above the first semiconductor chip.

20. The multi-chip package of claim 19, wherein at least some of the connecting terminals are arranged to a side of the first semiconductor chip
